(19) United States
(12) Patent Application Publication
(10) Pub. No.: US 2025/0112137 A1
(43) Pub. Date: Apr. 3, 2025

(54) INTEGRATED CIRCUIT PACKAGE AND METHOD

(71) Applicant: Taiwan Semiconductor Manufacturing Co., Ltd., Hsinchu (TW)

(72) Inventors: Shih-Wei Liu, Chiayi (TW); Po-Yao Lin, Zhudong Township (TW); Sing-Da Jiang, Taichung (TW); Tsunyen Wu, Hsinchu (TW); Kathy Wei Yan, Hsinchu (TW)

(21) Appl. No.: 18/478,592

(22) Filed: Sep. 29, 2023

(51) Int. Cl. H01L 23/498; H01L 21/48; H01L 21/56; H01L 23/00; H01L 23/31; H01L 23/373; H01L 25/065

(52) U.S. Cl. CPC H01L 23/49822; H01L 21/4857; H01L 21/486; H01L 21/4871; H01L 21/565; H01L 23/3107; H01L 23/3736; H01L 23/49838; H01L 23/49894; H01L 24/08; H01L 24/80; H01L 25/0655; H01L 2224/08225; H01L 2224/80895; H01L 2224/80896; H01L 2924/35121

(57) ABSTRACT

A method of manufacturing a device includes bonding a first die and a second die to a first side of a substrate, forming a stress buffer structure over the first die and the second die, where the stress buffer structure includes a first portion of a first via extending through a first insulating layer, a second portion of the first via extending through a second insulating layer, and a third portion of the first via extending through a third insulating layer, where the second portion of the first via is disposed between the first portion of the first via and the third portion of the first via, and where a diameter of the second portion of the first via is smaller than diameters of the first portion of the first via and the third portion of the first via, and depositing a metal layer over the stress buffer structure.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 illustrate cross-sectional views of intermediate steps during a process for forming semiconductor dies in accordance with some embodiments.

FIGS. 3 through 12B illustrate a top-down view and cross-sectional views of intermediate steps during a process for forming an integrated chip package in accordance with some embodiments.

FIGS. 13A and 13B illustrate a top-down view and a cross-sectional view of intermediate steps during a process for forming an integrated chip package in accordance with other embodiments.

FIG. 14 illustrates a cross-sectional view of intermediate steps during a process for forming an integrated chip package in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods applied to forming a 3D integrated chip (3DIC) package, such as a system on integrated chip (SoIC) package. Forming the integrated chip package comprises bonding two or more semiconductor dies (e.g., top dies) to a semiconductor wafer (e.g., a bottom die). A stress buffer structure is formed over and in physical contact with the two or more semiconductor dies (e.g., top dies). The stress buffer structure comprises one or more insulating layers with a plurality of copper vias that extend through the one or more insulating layers, wherein a percentage ratio of the total volume of the plurality of copper vias to the total volume of the stress buffer structure is in a range from 10 percent to 30 percent. A metal layer is formed over the stress buffer structure, and a thermal interface material (TIM) is applied to a top surface of the metal layer. A metal heat spreader (e.g., a copper lid) is subsequently placed on the integrated chip package, and the metal heat spreader makes contact with the metal layer by way of the TIM. Advantageous features of one or more embodiments described herein include the reduction of mechanical stresses due to a mismatch in the co-efficient of thermal expansions of a first material (e.g., copper) of the metal heat spreader and a second material (e.g., silicon) of the two or more semiconductor dies (e.g. the top dies). The stress buffer structure acts as an intermediate interface, absorbing or relaxing the mechanical stress caused by the mismatch in the co-efficient of thermal expansions between the first material and the second material. This reduces a risk of cracking at the interface between the two or more semiconductor dies (e.g. the top dies) and the metal heat spreader, and lowers the risk of delamination between the metal heat spreader and the two or more semiconductor dies (e.g. the top dies). In addition, the metal heat spreader and the stress buffer structure allow for improved and more effective heat dissipation from the integrated chip package, resulting in an improvement in device reliability and device performance.

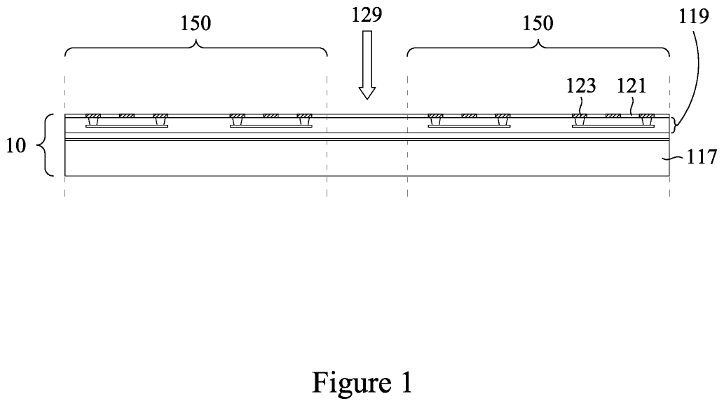

FIGS. 1 through 14 illustrate cross-sectional views and top-down views of intermediate steps during a process for forming an integrated chip package 100, in accordance with some embodiments. In FIG. 1, a wafer 10 is illustrated. The wafer 10 comprises semiconductor dies 150. Each of the semiconductor dies 150 may be a logic die (e.g., application processor (AP), central processing unit, microcontroller, etc.), a memory die (e.g., dynamic random access memory (DRAM) die, hybrid memory cube (HBC), a static random access memory (SRAM) die, a wide input/output (wideIO) memory die, a magnetoresistive random access memory (mRAM) die, a resistive random access memory (rRAM) die, etc.), a power management die (e.g., power management integrated circuit (PMIC) dies), a radio frequency (RF) die, a sensor die, a micro-electro-mechanical-system (MEMS) die, a signal processing die (e.g., digital signal processing (DSP) die), a front-end die (e.g., analog front-end (AFE) die), a biomedical die, or the like. Each semiconductor die 150 may also be a System-on-Chip (SoC) die, or the like. The wafer 10 may include a substrate 117 (e.g., a semiconductor substrate), an interconnect structure 119 disposed on the substrate 117, a bonding layer 121 disposed on the interconnect structure 119, and bonding pads 123 disposed in the bonding layer 121 and exposed at the front surface of the wafer 10. The side of the wafer 10 comprising the exposed bonding pads 123 and the bonding layer 121 may also be referred to subsequently as the front side of the wafer 10.

The substrate 117 of the wafer 10 may include a crystalline silicon wafer. The substrate 117 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 117 may comprise an active layer of a semiconductor-on-insulator (SOI) substrate. The substrate 117 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Active and/or passive devices, such as transistors, diodes, capacitors, resistors, etc., may be formed in and/or on the substrate 117. The devices may be interconnected by the interconnect structure 119. The interconnect structure 119 electrically connects the devices on the substrate 117 to form one or more integrated circuits. The interconnect structure 119 may include one or more dielectric layers (for example, one or more interlayer dielectric (ILD) layers, intermetal dielectric (IMD) layers, or the like) and interconnect wirings or metallization patterns embedded in the one or more dielectric layers. The material of the one or more dielectric layers may include silicon oxide (SiOₓ, where x>0), silicon nitride (SiNₓ, where x>0), silicon oxynitride (SiOₓN_{y}, where x>0 and y>0), or other suitable dielectric material. The interconnect wirings may include metallic wirings. For example, the interconnect wirings include copper wirings, copper pads, aluminum pads or combinations thereof that are formed by one or more single damascene processes, dual damascene processes, or the like. The side of the wafer 10 comprising an exposed back side surface of the substrate 117 may also be referred to subsequently as the back side of the wafer 10.

The bonding layer 121 may comprise a dielectric layer. Bonding pads 123 are embedded in the bonding layer 121, and the bonding pads 123 allow connections to be made to the interconnect structure 119 and the devices on the substrate 117. The material of the bonding layer 121 may be silicon oxide (SiOₓ, where x>0), silicon nitride (SiNₓ, where x>0), silicon oxynitride (SiOₓN_{y}, where x>0 and y>0), tetraethyl orthosilicate (TEOS), or other suitable dielectric material, and the bonding pads 123 may comprise conductive pads (e.g., copper pads), conductive vias (e.g., copper vias), or combinations thereof. The bonding layer 121 may be formed by depositing a dielectric material over the interconnect structure 119 using a chemical vapor deposition (CVD) process (e.g., a plasma enhanced CVD process or other suitable process); patterning the dielectric material to form the bonding layer 121 including openings or through holes; and filling conductive material in the openings or through holes defined in the bonding layer 121 to form the bonding pads 123 embedded in the bonding layer 121.

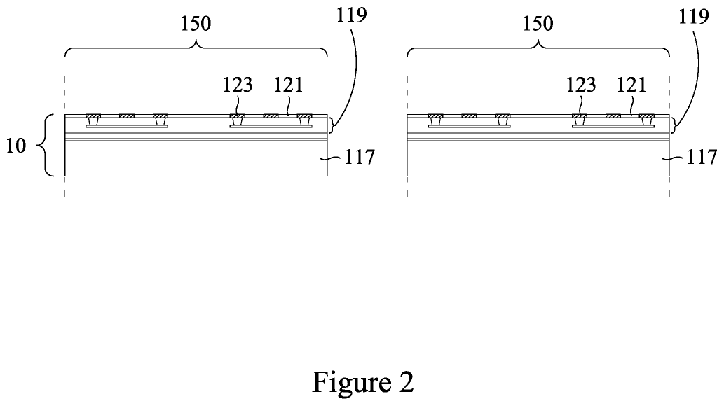

In FIG. 2, a dicing process is performed along a dicing path 129 that is shown previously in FIG. 1. The dicing process singulates the semiconductor dies 150 from each other along the dicing path 129. The dicing path 129 is disposed between adjacent semiconductor dies 150. The dicing process may comprise, for example, a blade dicing process using an abrasive disc or blade saw rotating at high speed to cut along the dicing path 129. The blade tip may comprise abrasive grit or a thin diamond layer.

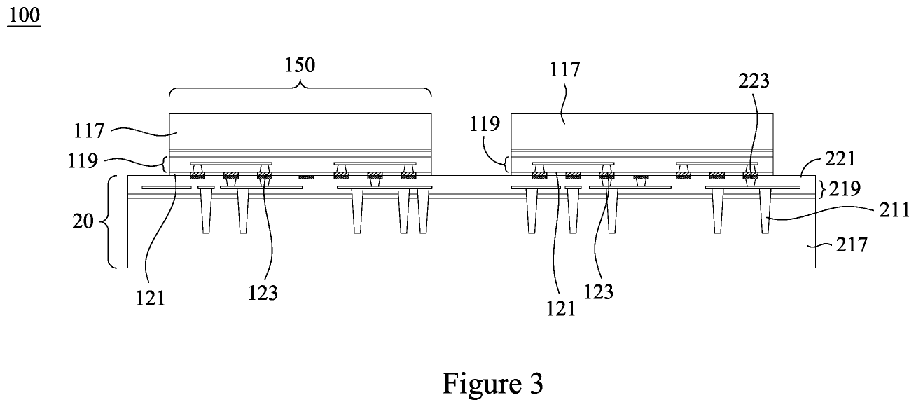

In FIG. 3, a semiconductor wafer 20 is bonded to the semiconductor dies 150. The wafer 20 may also be subsequently referred to as a bottom die. The materials and formation processes of the features in the wafer 20 may be found by referring to the like features in the wafer 10, with the like features in the wafer 10 starting with number “1,” which features correspond to the features in the wafer 20 and having reference numerals starting with number “2.” For example, the wafer 20 may include a substrate 217 having devices (e.g., transistors, capacitors, diodes, resistors, or the like) formed thereon and an interconnect structure 219. The interconnect structure 219 electrically connects the devices on the substrate 217 to form one or more integrated circuits. The interconnect structure 219 includes one or more dielectric layers (for example, one or more interlayer dielectric (ILD) layers, intermetal dielectric (IMD) layers, or the like) and interconnect wirings or metallization patterns embedded in the one or more dielectric layers.

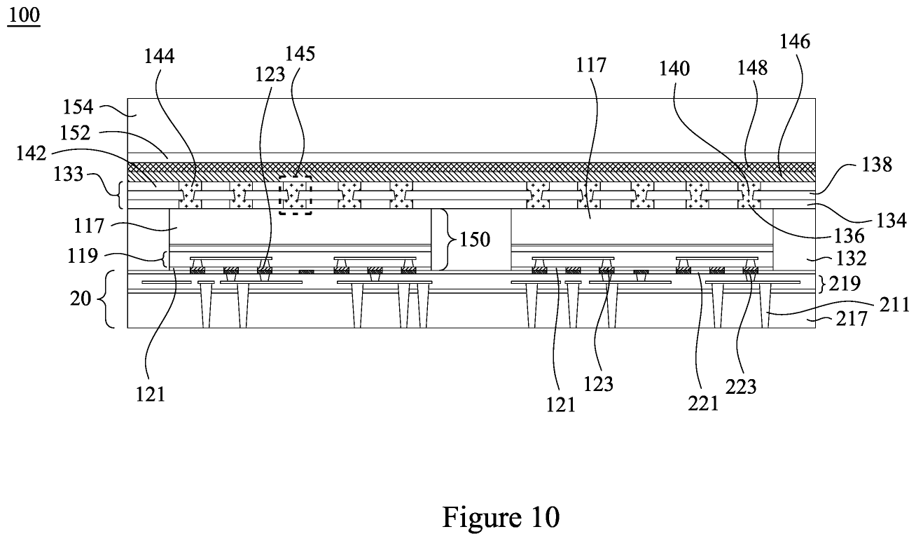

A bonding layer 221 is disposed on the interconnect structure 219, and bonding pads 223 are disposed in the bonding layer 221. The bonding pads 223 allow connections to be made to the interconnect structure 219 and the devices on the substrate 217. The wafer 20 further includes through substrate vias (TSVs) 211 which may be electrically connected to the metallization patterns in the interconnect structure 219. The TSVs 211 may be formed by forming recesses in the substrate 217 by, for example, etching, milling, laser techniques, a combination thereof, and/or the like. A thin barrier layer may be conformally deposited over the front side of the substrate 217 and in the openings, such as by chemical vapor deposition (CVD), atomic layer deposition (ALD), physical vapor deposition (PVD), thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the front side of the substrate 217 by, for example, chemical mechanical polishing. Thus, in some embodiments, the TSVs 211 may comprise a conductive material and a thin barrier layer between the conductive material and the substrate 217. In subsequent processing steps, the substrate 217 may be thinned to expose the TSVs 211 (see FIG. 10). After thinning, the TSVs 211 provide electrical connection from a back side of the substrate 217 to a front side of the substrate 217. In various embodiments, the back side of the substrate 217 may refer to a side of the substrate 217 opposite to the devices and the interconnect structure 219 while the front side of the substrate 217 may refer to a side of the substrate 217 on which the devices and the interconnect structure 219 are disposed.

Still referring to FIG. 3, the semiconductor dies 150 are bonded to the wafer 20, for example, in a hybrid bonding configuration. The semiconductor dies 150 are disposed face down such that front sides of the semiconductor dies 150 face the wafer 20 and back sides of the semiconductor dies 150 face away from the wafer 20. The semiconductor dies 150 are bonded to the bonding layer 221 on the front side of the wafer 20 and the bonding pads 223 in the bonding layer 221. For example, the bonding layer 121 of the semiconductor dies 150 may be directly bonded to the bonding layer 221 of the wafer 20, and bonding pads 123 of the semiconductor dies 150 may be directly bonded to the bonding pads 223 of the wafer 20. In an embodiment, the bond between the bonding layer 121 and the bonding layer 221 may be an oxide-to-oxide bond, or the like. The hybrid bonding process further directly bonds the bonding pads 123 of the semiconductor dies 150 to the bonding pads 223 of the wafer 20 through direct metal-to-metal bonding. Thus, electrical connection between the semiconductor dies 150 and the wafer 20 is provided by the physical connection of the bonding pads 123 to the bonding pads 223.

As an example hybrid bonding process starts with aligning the semiconductor dies 150 with the wafer 20, for example, by applying a surface treatment to one or more of the bonding layer 121 or the bonding layer 221. The surface treatment may include a plasma treatment. The plasma treatment may be performed in a vacuum environment. After the plasma treatment, the surface treatment may further include a cleaning process (e.g., a rinse with deionized water, or the like) that may be applied to one or more of the bonding layer 121 or the bonding layer 221. The hybrid bonding process may then proceed to aligning the bonding pads 123 to the bonding pads 223. Next, the hybrid bonding includes a pre-bonding step, during which the semiconductor dies 150 are put in contact with the wafer 20. The pre-bonding may be performed at room temperature (e.g., between about 21° C. and about 25° C.). The hybrid bonding process continues with performing an anneal, for example, at a temperature between about 150° C. and about 400° C. for a duration between about 0.5 hours and about 3 hours, so that the metal in bonding pads 123 (e.g., copper) and the metal of the bonding pads 223 (e.g., copper) inter-diffuses to each other, and hence the direct metal-to-metal bonding is formed. Although two semiconductor dies 150 are illustrated as being bonded to the wafer 20, other embodiments may include any number of semiconductor dies 150 bonded to the wafer 20.

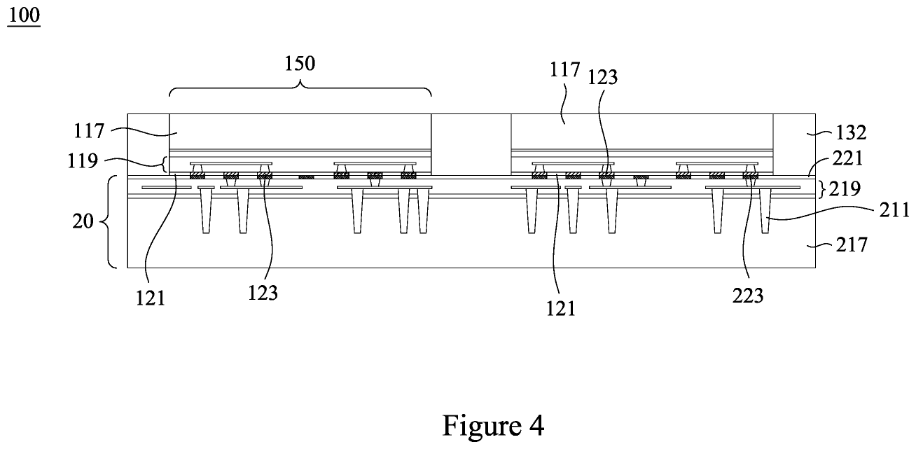

In FIG. 4, an encapsulant 132 is formed over the wafer 20 and the semiconductor dies 150, in order to encapsulate each of the semiconductor dies 150. The encapsulant 132 may be formed using compression molding, transfer molding, spin-coating, or the like. The encapsulant 132 may be an epoxy or a molding compound resin such as polyimide, polyphenylene sulfide (PPS), polyetheretherketone (PEEK), poly ether sulphone (PES), a heat resistant crystal resin, combinations of these, or the like.

After the formation of the encapsulant 132, a planarization process is performed to remove excess portions of the encapsulant 132, and to expose top surfaces of the semiconductor dies 150. The planarization process may comprise a grinding process, a CMP process, or the like. As illustrated in FIG. 4, the planarization process may result in top surfaces of the semiconductor dies 150 being level with top surfaces of the encapsulant 132.

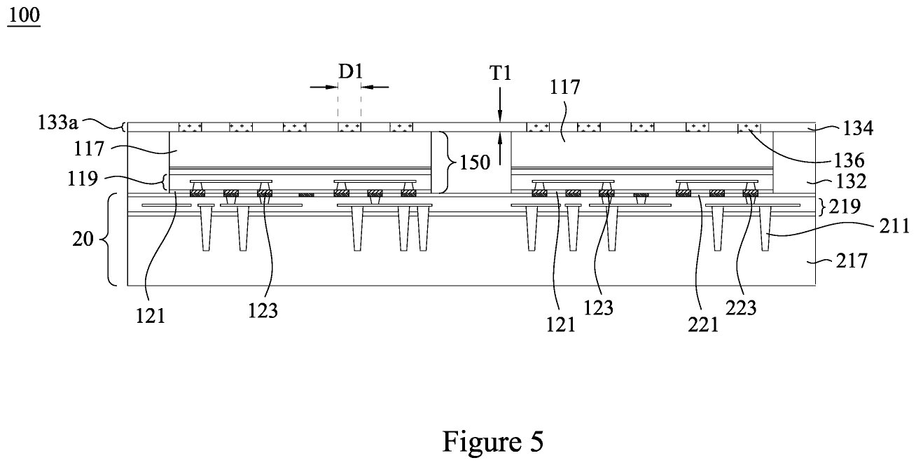

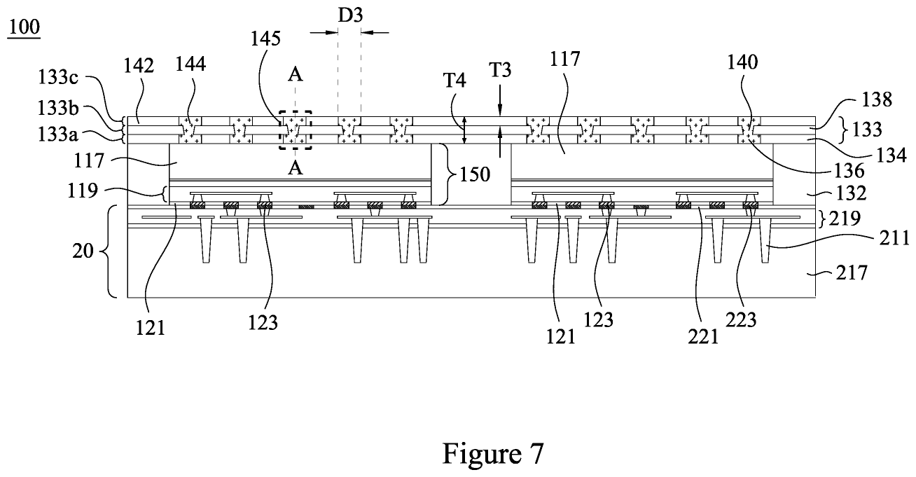

FIGS. 5 through 7 illustrate the formation of a stress buffer structure 133 (see FIG. 7) over the top surfaces of the semiconductor dies 150 and the top surfaces of the encapsulant 132. The stress buffer structure 133 may include one or more insulating layer(s) and respective via(s) within the insulating layer(s). Each insulating layer and its respective vias disposed within the insulating layer can collectively be referred to as a stress buffer layer.

In FIG. 5, a bottom stress buffer layer 133a of the stress buffer structure 133 is formed over the top surfaces of the semiconductor dies 150 and the top surfaces of the encapsulant 132. The bottom stress buffer layer 133a comprises an insulating layer 134 and bottom vias 136 extending through the insulating layer 134. The bottom vias 136 are formed over the top surfaces of the semiconductor dies 150 and optionally may also be formed over the top surfaces of the encapsulant 132 by initially forming a first seed layer (not shown) of one or more thin layers of a conductive material that aids in the formation of a thicker layer during subsequent processing steps. The first seed layer is formed over the top surfaces of the semiconductor dies 150 and the top surfaces of the encapsulant 132. The first seed layer may comprise a layer of copper, titanium, or the like, that is formed using processes such as sputtering, evaporation, PECVD, or the like. A photoresist (also not shown) may then be formed and patterned to cover the first seed layer using, for example, a spin coating technique. Once the photoresist has been formed and patterned, a conductive material may be formed in the openings of the patterned photoresist on the first seed layer. The conductive material may be a material such as copper, or the like. The conductive material may be formed through a deposition process such as electroplating, electroless plating, or the like. Once the conductive material has been formed, the photoresist may be removed through a suitable removal process such as ashing or chemical stripping. Additionally, after the removal of the photoresist, those portions of the first seed layer that were covered by the photoresist may be removed through, for example, a suitable wet etch process or dry etch process, which may use the conductive material as an etch mask. The remaining portions of the first seed layer and conductive material form the bottom vias 136. In some embodiments, a diameter D1 of each the bottom vias 136 may be in a range from 8 μm to 20 μm.

After the formation of the bottom vias 136, the insulating layer 134 is formed over the bottom vias 136, the top surfaces of the semiconductor dies 150, and the top surfaces of the encapsulant 132. The insulating layer 134 may comprise one or more dielectric materials such as a low-temperature polyimide (LTPI) material, or the like. The insulating layer 134 may be formed by a process such as coating, (e.g., spin-coating), or the like. After the formation of the insulating layer 134, excess portions of the insulating layer 134 may be planarized using a grinding process, a CMP process, or the like, to remove a portion of the insulating layer 134 and expose top surfaces of the bottom vias 136. The exposed bottom vias 136 and the insulating layer 134 thus form the bottom stress buffer layer 133a. As illustrated in FIG. 5, the planarization may result in the top surfaces of the bottom vias 136 being level with top surfaces of the insulating layer 134. In an embodiment, the bottom stress buffer layer 133a may have a thickness T1 that is up to 10 μm.

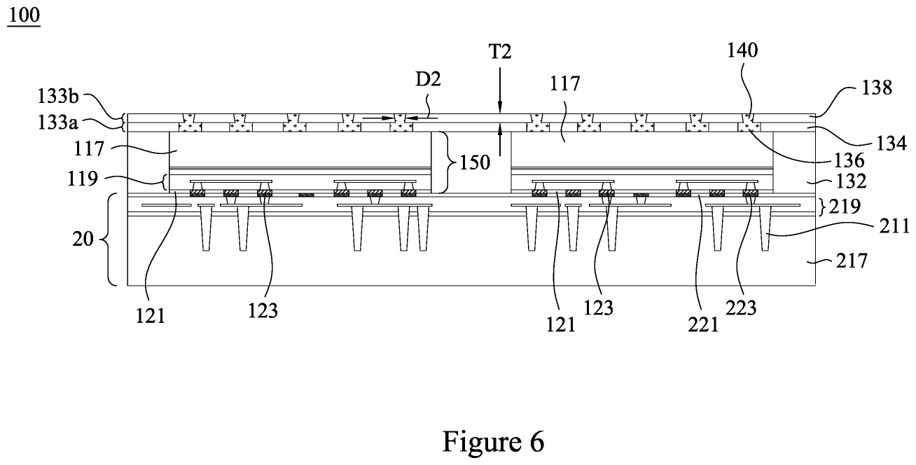

In FIG. 6, a middle stress buffer layer 133b of the stress buffer structure 133 is formed over the bottom stress buffer layer 133a. The middle stress buffer layer 133b may comprise an insulating layer 138 and middle vias 140 extending through the insulating layer 138. The middle stress buffer layer 133b may be formed using materials and processes similar to the bottom stress buffer layer 133a. For example, the middle vias 140 may be formed using materials and processes similar to those that were described previously in FIG. 5 for the formation of the bottom vias 136, and the insulating layer 138 may be formed using materials and processes similar to those that were described previously in FIG. 5 for the formation of the insulating layer 134. As an example, to form the middle vias 140, a photoresist is placed and patterned on top of the bottom stress buffer layer 133a in a desired pattern for the middle vias 140. The patterned openings of the photoresist are disposed over respective ones of the bottom vias 136, such that each opening exposes a top surface of a respective bottom via 136. A conductive material (e.g., copper or the like) is then formed in the patterned openings of the photoresist using e.g., a plating process, or the like. Note that the formation of a second seed layer prior to forming the conductive material is optional, as the bottom via may comprise copper, which facilitates the plating process used to form the conductive material. The photoresist may then be removed through a suitable removal process such as ashing or chemical stripping. The remaining portions of the conductive material form the middle vias 140. In this manner, each of the middle vias 140 overlap and are in physical contact with a respective bottom via 136. In an embodiment, a diameter D2 of each the middle vias 140 may be in a range from 5 μm to 15 μm. In an embodiment, the diameter D2 is smaller than the diameter D1. In an embodiment, the diameter D2 of each of the middle vias 140 may decrease in a vertical direction (e.g., each middle via 140 may have a taper) moving from a top surface of the middle via 140 to a bottom surface of the middle via 140.

After the formation of the middle vias 140, the insulating layer 138 is formed over the middle vias 140 and the bottom stress buffer layer 133a, such as over the bottom vias 136 and the insulating layer 134. The insulating layer 138 is formed using materials and processes similar to those that were described previously in FIG. 5 for the formation of the insulating layer 134. After the formation of the insulating layer 138, excess portions of the insulating layer 138 may be planarized using a grinding process, a CMP process, or the like, to remove a portion of the insulating layer 138 and expose top surfaces of the middle vias 140. The exposed middle vias 140 and the insulating layer 138 thus form the middle stress buffer layer 133b. As illustrated in FIG. 6, the planarization may result in the top surfaces of the middle vias 140 being level with top surfaces of the insulating layer 138. In an embodiment, the middle stress buffer layer 133b may have a thickness T2 that is up to 20 μm.

Although FIG. 6 illustrates only one middle stress buffer layer 133b over the bottom stress buffer layer 133a, any number of middle stress buffer layers 133b may be formed comprising one or more additional insulating layers and respective middle vias extending through the one or more additional insulating layers. The insulating layers and the middle vias may be formed using processes and materials similar to those used for the formation of the insulating layer 138 and the middle vias 140, respectively. The steps described above may be repeated until a suitable number of middle stress buffer layers 133b is formed.

In FIG. 7, a top stress buffer layer 133c of the stress buffer structure 133 is formed over the middle stress buffer layer 133b. The top stress buffer layer 133c may comprise an insulating layer 142 and top vias 144 extending through the insulating layer 142. The top stress buffer layer 133c may be formed using materials and processes similar to the bottom stress buffer layer 133a and the middle stress buffer layer 133b. For example, the top vias 144 may be formed using materials and processes similar to those that were described previously in FIGS. 5 and 6 for the formation of the bottom vias 136 and the middle vias 140, and the insulating layer 142 may be formed using materials and processes similar to those that were described previously in FIGS. 5 and 6 for the formation of the insulating layer 134 and the insulating layer 138. As an example, to form the top vias 144, a third seed layer is formed over the middle stress buffer layer 133b such as over top surfaces of the middle vias 140 and insulating layer 138. The third seed layer is formed using similar processes and similar materials as those described previously in FIG. 5 for the formation of the first seed layer. A photoresist is placed and patterned on top of the third seed layer in a desired pattern for the top vias 144. A conductive material (e.g., copper or the like) is then formed in the patterned openings of the photoresist using e.g., a plating process, or the like. The photoresist may then be removed through a suitable removal process such as ashing or chemical stripping. Additionally, after the removal of the photoresist, those portions of the third seed layer that were covered by the photoresist may be removed through, for example, a suitable wet etch process or dry etch process, which may use the conductive material as an etch mask. The remaining portions of the third seed layer and conductive material form the top vias 144. In some embodiments, a diameter D3 of each the top vias 144 may be in a range from 8 μm to 20 μm. The diameter D3 may be larger than the diameter D2. In an embodiment, the diameter D3 may be equal to or be different from the diameter D1.

A portion of each of the top vias 144 is disposed to overlap and be in physical contact with a respective middle via 140 below it, and the respective middle via 140 is disposed to overlap and be in physical contact with a respective bottom via 136 below it. In this manner, each top via 144, the respective middle via 140 disposed under and in physical contact with the top via 144, and the respective bottom via 136 disposed under and in physical contact with the middle via 140, form a combined via 145. The combined via 145 may also be referred to subsequently as a stress buffer via. In addition, portions of each top via 144 also overlap the insulating layer 138. In an embodiment, a vertical line A-A passes through a center of the combined via 145, wherein the line A-A passes through a center of the respective top via 144, a center of the respective middle via 140, and a center of the respective bottom via 136 of the combined via 145.

After the formation of the top vias 144, the insulating layer 142 is formed over the top vias 144 and the middle stress buffer layer 133b. The insulating layer 142 is formed using materials and processes similar to those that were described previously in FIGS. 5 and 6 for the formation of the insulating layer 134 and the insulating layer 138. After the formation of the insulating layer 142, excess portions of the insulating layer 142 may be planarized using a grinding process, a CMP process, or the like, to remove a portion of the insulating layer 142 and expose top surfaces of the top vias 144. The exposed top vias 144 and the insulating layer 142 thus form the top stress buffer layer 133c. As illustrated in FIG. 7, the planarization may result in the top surfaces of the top vias 144 being level with top surfaces of the insulating layer 142. In an embodiment, the top stress buffer layer 133c may have a thickness T3 that is up to 10 μm. After the formation of the top stress buffer layer 133c, the stress buffer structure 133 may have a total thickness T4 that may be up to 100 μm.

Although FIG. 7 illustrates only one middle stress buffer layer 133b over the bottom stress buffer layer 133a, and one top stress buffer layer 133c over the middle stress buffer layer 133b, any number of middle stress buffer layers 133b may be formed comprising one or more additional first insulating layers and respective middle vias extending through the one or more additional first insulating layers, and any number of top stress buffer layers 133c may be formed comprising one or more additional second insulating layers and respective top vias extending through the one or more additional second insulating layers. The first insulating layers and the middle vias may be formed using processes and materials similar to those used for the formation of the insulating layer 138 and the middle vias 140, respectively. The second insulating layers and the top vias may be formed using processes and materials similar to those used for the formation of the insulating layer 142 and the top vias 144, respectively. The steps described above may be repeated until a suitable number of middle stress buffer layers 133b and top stress buffer layers 1330 are formed. For example, in an embodiment, the total number of layers of the stress buffer structure 133 (e.g., including the bottom stress buffer layer 133a, the middle stress buffer layers 133b, and the top stress buffer layers 133c) may be in a range from 3 to 15.

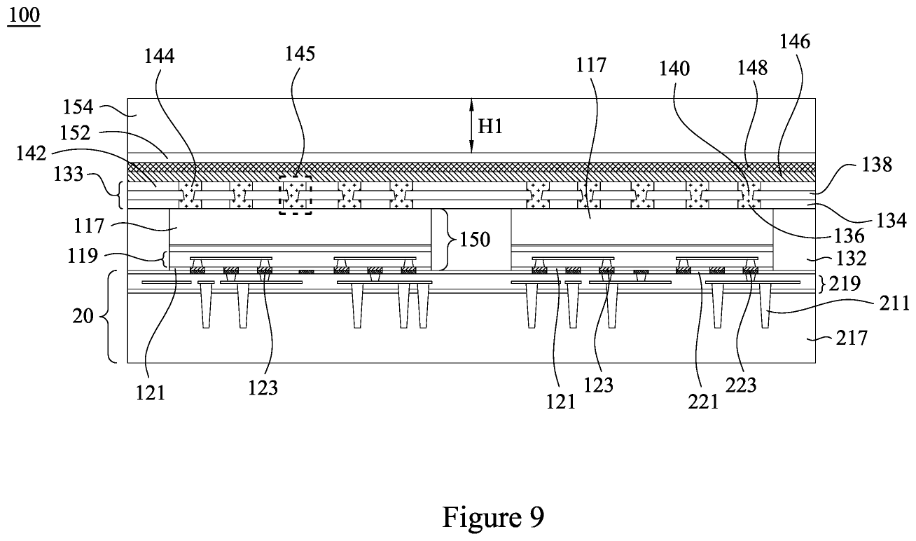

The combined vias 145 (e.g., each combined via 145 comprising a top via 144, a respective middle via 140, and a respective bottom via 136) extend through the stress buffer structure 133. First ones of the combined vias 145 may be disposed over and be in physical contact with the semiconductor dies 150, and optionally, second ones of the combined vias 145 may be disposed over and in physical contact with the encapsulant 132. For example, the combined vias 145 may be in physical contact with a silicon surface (e.g., of the substrate 117) of the semiconductor dies 150. The combined vias 145 allow the generated heat from the semiconductor dies 150 to travel away from the semiconductor dies 150 and the surrounding encapsulant 132 through the combined vias 145, and on to a metal heat spreader 154 (shown subsequently in FIG. 9) where this heat is dissipated. In this way, the combined vias 145 are thermally coupled to the semiconductor dies 150, serving as an efficient heat conduit, and facilitating the transfer of heat away from the semiconductor dies 150 and directing it towards the metal heat spreader 154 for effective dissipation.

After the formation of the stress buffer structure 133, a percentage ratio of the total volume of the combined vias 145 (e.g., comprising a material such as copper) to the total volume of the stress buffer structure 133 (e.g., comprising the combined vias 145 and the insulating layers 134, 138, and 142) is in a range from 10 percent to 30 percent.

Advantages may be achieved as a result of forming the stress buffer structure 133 over the semiconductor dies 150 and the encapsulant 132, such that the stress buffer structure 133 is disposed between the semiconductor dies 150 and the encapsulant 132, and the subsequently attached metal heat spreader 154 (shown in FIG. 9). The stress buffer structure 133 has a total thickness T4 that may be up to 100 μm, and comprises up to 15 insulating layers (e.g., the insulating layers 134, 138, and 142), and the combined vias 145 that extend through the insulating layers (e.g., the insulating layers 134, 138, and 142). The combined vias 145 comprise copper, and the insulating layers (e.g., the insulating layers 134, 138, and 142) comprise a low-temperature polyimide (LTPI) material. These advantages include a reduction of mechanical stresses due to a mismatch in the co-efficient of thermal expansions of a first material (e.g., copper) of the metal heat spreader 154 and a second material (e.g., silicon) of the semiconductor dies 150. The stress buffer structure 133 acts as an intermediate interface, absorbing or relaxing the mechanical stress caused by the mismatch in the co-efficient of thermal expansions between the first material and the second material. This reduces a risk of cracking at the interface between the semiconductor dies 150 and the metal heat spreader 154, and lowers the risk of possible delamination between the metal heat spreader 154 and the semiconductor dies 150. In addition, the metal heat spreader 154 and the stress buffer structure 133 allow for improved and more effective heat dissipation from the integrated chip package 100, resulting in an improvement in device reliability and device performance.

Additional advantages can be achieved by forming the stress buffer structure 133, wherein a percentage ratio of the total volume of the copper of the combined vias 145 to the total volume of the stress buffer structure 133 is in a range from 10 percent to 30 percent. For example, if a percentage ratio of the total volume of the copper of the combined vias 145 to the total volume of the stress buffer structure 133 is below 10 percent, there will be an inadequate heat conduit to facilitate the transfer of heat away from the semiconductor dies 150 and to direct it towards the metal heat spreader 154. This will lead to inadequate heat dissipation from the integrated chip package 100. Additionally, if a percentage ratio of the total volume of the copper of the combined vias 145 to the total volume of the stress buffer structure 133 is above 30 percent, there will be unacceptably high mechanical stresses generated due to a mismatch in the co-efficient of thermal expansions of the copper in the combined vias 145 and the second material (e.g., silicon) of the semiconductor dies 150. This will therefore mean an increased risk of cracking at the interface between the semiconductor dies 150 and the stress buffer structure 133, and an increased risk of delamination between the stress buffer structure 133 and the semiconductor dies 150.

Further advantages can be achieved by forming the stress buffer structure 133 having the thickness T4 that is up to 100 μm, wherein the top vias 144 have the diameter D3 that is in a range from 8 μm to 20 μm, wherein the middle vias 140 have the diameter D2 that is in a range from 5 μm to 15 μm, and wherein the bottom vias 136 have the diameter D1 that is in a range from 8 μm to 20 μm. These advantages include facilitating and making it much easier to form the stress buffer structure 133 while maintaining (e.g., by varying the thickness T4 and the diameters D1, D2, and D3 within the above dimensional range parameters) a desired percentage ratio of the total volume of the copper of the combined vias 145 to the total volume of the stress buffer structure 133, wherein the percentage ratio is in a range from 10 percent to 30 percent.

Even more advantages can be achieved by forming the stress buffer structure 133, wherein the top vias 144 have the diameter D3 that is in a range from 8 μm to 20 μm, wherein the middle vias 140 have the diameter D2 that is in a range from 5 μm to 15 μm, and wherein the bottom vias 136 have the diameter D1 that is in a range from 8 μm to 20 μm. The diameter D1 and the diameter D3 are larger than the diameter D2, and the diameter D2 of each of the middle vias 140 may decrease in a vertical direction (e.g., each middle via 140 may have a taper) moving from a top surface of the stress buffer structure 133 towards a bottom surface of the stress buffer structure 133. These advantages include a more effective distribution and dispersion of mechanical stresses (e.g., generated due to a mismatch in the co-efficient of thermal expansions of the first material (e.g., copper) of the metal heat spreader 154 and the second material (e.g., silicon) of the semiconductor dies 150) along the height of the stress buffer structure 133, as a result of the transitions of the combined vias 145 from one diameter to another. In addition, stress is dispersed more smoothly along the height of the stress buffer structure 133 as a result of the tapering effect of the middle vias 140. This reduces possible areas of stress concentrations within the stress buffer structure 133 and reduces a risk of cracking at the interface between the semiconductor dies 150 and the stress buffer structure 133. As a result, a risk of delamination between the stress buffer structure 133 and the semiconductor dies 150 is reduced.

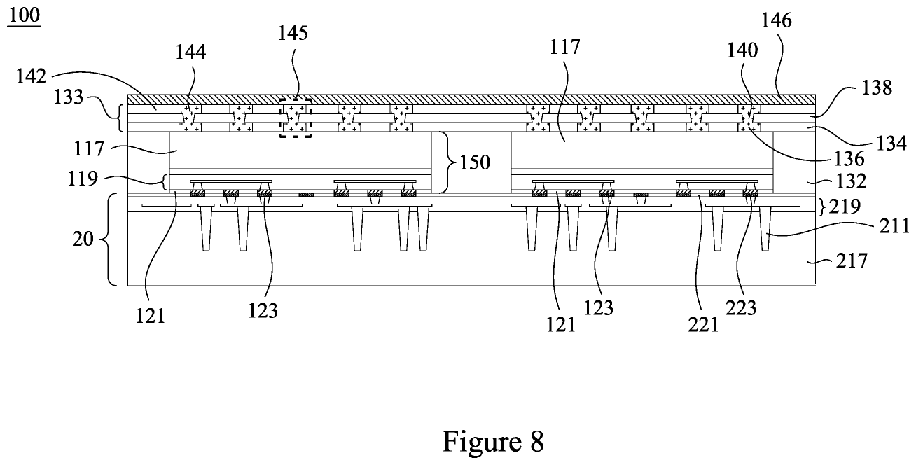

In FIG. 8, a metal layer 146 is formed over the stress buffer structure 133, such as over the insulating layer 142 and the top vias 144 of the top stress buffer layer 133c. The metal layer 146 may comprise a layer of copper, titanium, or the like, that is formed using processes such as sputtering, evaporation, CVD, PECVD, or the like.

Advantages can be achieved by forming the metal layer 146 over the stress buffer structure 133. These include, the metal layer 146 serving as a highly conductive pathway for heat transfer, allowing uniform distribution of heat from the underlying stress buffer structure 133 to the subsequently attached metal heat spreader 154 (shown in FIG. 9). This prevents localized hotspots from forming above the combined vias 145, and allows for improved and more effective heat dissipation from the integrated chip package 100 through the metal heat spreader 154, resulting in an improvement in device reliability and device performance.

In FIG. 9, a thermal interface material (TIM) 148 is applied to the top surface of the metal layer 146. The TIM 148 is formed of a thermally conductive material. Acceptable thermally conductive materials include thermal grease; a phase change material; a metal filled polymer matrix; solder alloys of lead, tin, indium, silver, copper, bismuth, and the like (such as indium or lead/tin alloy); or the like. If the TIM 148 is a solid material, it may be heated to a temperature at which it undergoes a solid to liquid transition and then may be applied in liquid form to the top surface of the metal layer 146.

After the application of the TIM 148 to the top surface of the metal layer 146, a metal heat spreader 154 is subsequently coupled to the top surface of the metal layer 146. The metal heat spreader 154 is placed on the top surface of the metal layer 146 using, e.g., a pick and place process. The metal heat spreader 154 makes contact with the top surface of the metal layer 146 by way of the TIM 148. The metal heat spreader 154 may comprise a metal such as copper, or the like. The metal heat spreader 154 may also be referred to subsequently as a copper lid. In an embodiment, a height H1 of the metal heat spreader 154 may be up to 5 mm.

In an embodiment, the metal heat spreader 154 may have a metal layer 152 disposed over a first surface of the metal heat spreader 154. The metal layer 152 may comprise a material that is different from a material of the metal heat spreader 154. For example, the metal layer 152 may comprise titanium, or the like, that is formed by sputtering, evaporation, CVD, PECVD, or the like. In this embodiment, when the metal heat spreader 154 is coupled to the top surface of the metal layer 146, the first surface of the metal heat spreader 154 faces the top surface of the metal layer 146, such that the metal layer 152 is disposed between the metal layer 146 and the metal heat spreader 154.

Advantages can be achieved by forming the stress buffer structure 133 over and in physical contact with the semiconductor dies 150 and the encapsulant 132. The stress buffer structure 133 may comprise 3 to 15 insulating layers (e.g., the insulating layers 134, 138, and 142), and the combined vias 145 that extend through the insulating layers (e.g., the insulating layers 134, 138, and 142). The combined vias 145 comprise copper, and the insulating layers (e.g., the insulating layers 134, 138, and 142) comprise a low-temperature polyimide (LTPI) material, wherein a percentage ratio of the total volume of the copper of the combined vias 145 to the total volume of the stress buffer structure 133 is in a range from 10 percent to 30 percent. The metal layer 146 is formed over the stress buffer structure 133, and the metal heat spreader 154 is then coupled to and makes contact with the metal layer 146 by way of the TIM 148. These advantages include a reduction of mechanical stresses due to a mismatch in the co-efficient of thermal expansions of a first material (e.g., copper) of the metal heat spreader 154 and a second material (e.g., silicon) of the semiconductor dies 150. The stress buffer structure 133 acts as an intermediate interface, absorbing or relaxing the mechanical stress caused by the mismatch in the co-efficient of thermal expansions between the first material and the second material. This reduces a risk of cracking at the interface between the semiconductor dies 150 and the metal heat spreader 154, and lowers the risk of possible delamination between the metal heat spreader 154 and the semiconductor dies 150. In addition, the metal heat spreader 154 and the stress buffer structure 133 allow for improved and more effective heat dissipation from the integrated chip package 100, resulting in an improvement in device reliability and device performance.

In FIG. 10, a thinning process of a back side of the substrate 217 is performed to expose the TSVs 211. The thinning process of the back side of the substrate 217 may be performed by a planarization process such as CMP, grinding, or etching. The thinning process may result in surfaces of the TSVs 211 being level with surfaces of the back side of the substrate 217.

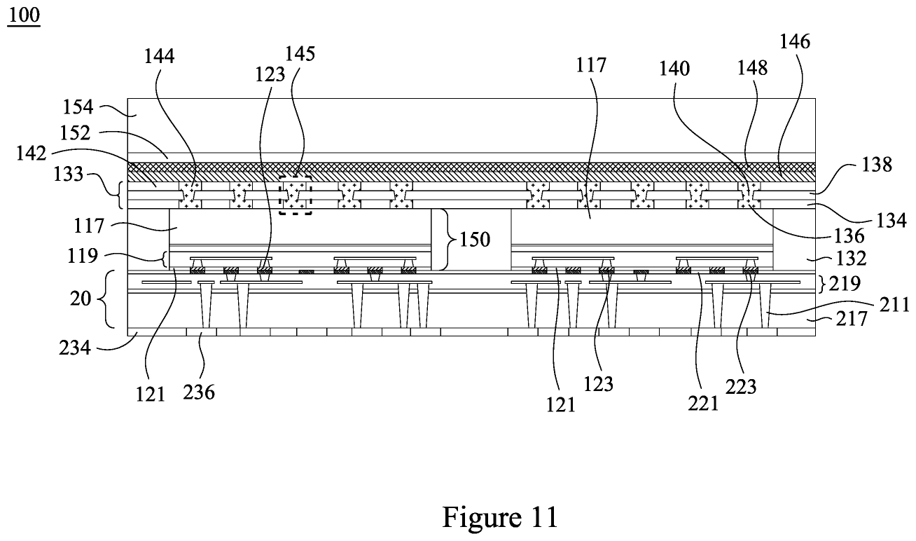

In FIG. 11, a dielectric layer 234 is formed on the back side of the substrate 217 and on the exposed surfaces of the TSVs 211. The dielectric layer 234 may comprise silicon oxide, silicon nitride, silicon carbide, silicon oxynitride, low-K dielectric material, such as phosphosilicate glass (PSG), borophosphosilicate glass (BPSG), fluorosilicate glass (FSG), SiOxCy, Spin-On-Glass, Spin-On-Polymers, silicon carbon material, compounds thereof, composites thereof, combinations thereof, or the like. The dielectric layer 234 may be deposited by any suitable method, such as, CVD, PECVD, spinning, or the like.

Metallization patterns 236 may be formed in the dielectric layer 234, for example, by using photolithography techniques to deposit and pattern a photoresist material on the dielectric layer 234 to expose portions of the dielectric layer 234 that are to become the metallization patterns 236. An etch process, such as an anisotropic dry etch process, may be used to create openings in the dielectric layer 234 corresponding to the exposed portions of the dielectric layer 234. The openings in the dielectric layer 234 may expose the TSVs 211. A seed layer (not separately illustrated) is formed over the exposed surfaces of the dielectric layer 234 and in the openings in the dielectric layer 234. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization patterns 236. The patterning forms openings through the photoresist to expose the seed layer. A conductive material is then formed in the openings and on the exposed portions of the seed layer. The conductive material may be formed by plating, such as electroplating, electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material in the dielectric layer 234 form the metallization patterns 236. These metallization patterns 236 will be used to electrically connect the TSVs 211 to external devices. In some embodiments, the metallization patterns 236 may also include under Bump Metallizations (UBMs).

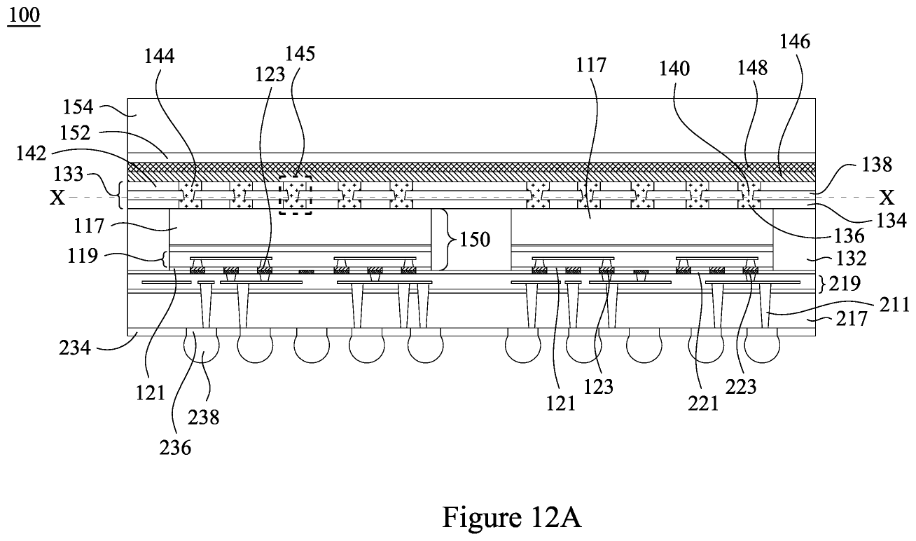

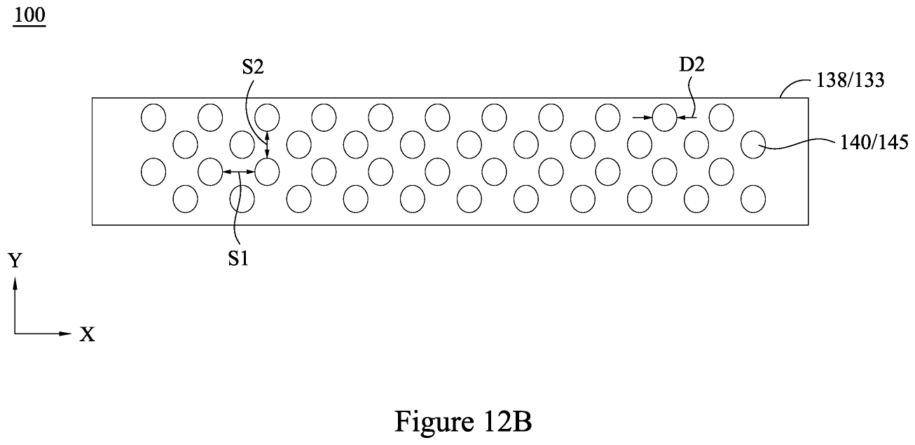

FIG. 12A illustrates the formation of conductive connectors 238 on the metallization patterns 236. FIG. 12B illustrates a top-down view of the integrated chip package 100 along a line X-X shown in FIG. 12A. In FIG. 12A, the conductive connectors 238 are formed such that they are disposed on the metallization patterns 236, and are electrically coupled to the semiconductor dies 150 through the TSVs 211. The conductive connectors 238 may comprise controlled collapse chip connection (C4) bumps, ball grid array (BGA) connectors, solder balls, or the like. The conductive connectors 238 may comprise a conductive material such as solder, copper, aluminum, gold, nickel, silver, palladium, tin, the like, or a combination thereof. In some embodiments, the conductive connectors 238 are formed by initially forming a layer of solder through evaporation, electroplating, printing, solder transfer, ball placement, or the like. Once a layer of solder has been formed on the structure, a reflow may be performed in order to shape the material into the desired bump shapes.

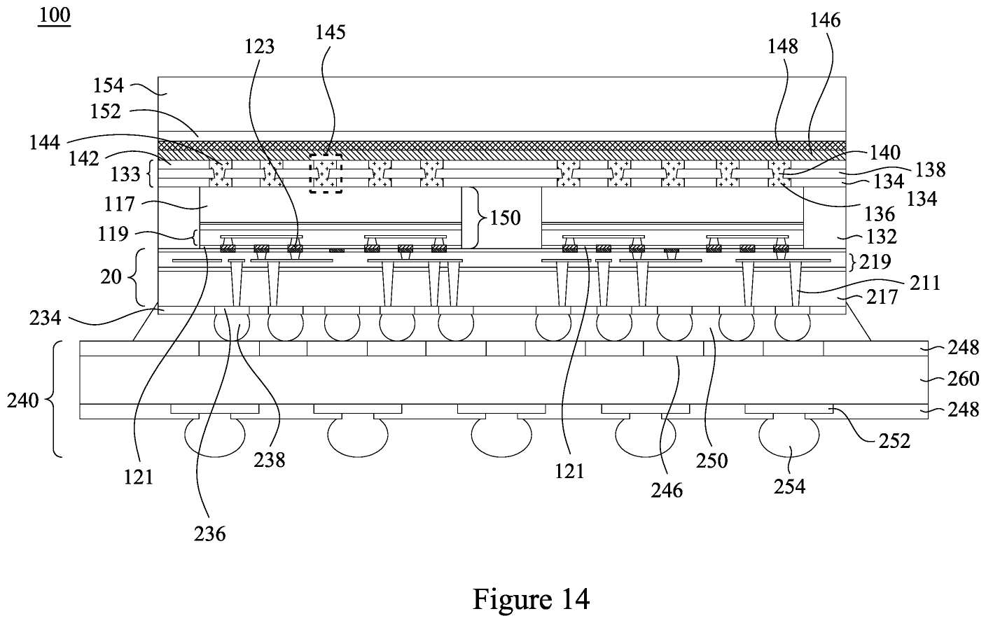

The conductive connectors 238 will be used to bond to the integrated chip package 100 to an additional electrical component, which may be a semiconductor substrate, a package substrate, a Printed Circuit Board (PCB), or the like (see FIG. 14).

In FIG. 12B, a top-down view is shown along a line X-X that is illustrated in FIG. 12A, wherein the line X-X passes through a center of the middle stress buffer layer 133b of the stress buffer structure 133. The FIG. 12B therefore shows the insulating layer 138 of the stress buffer structure 133, and the middle vias 140 of respective combined vias 145 that extend through the stress buffer structure 133. FIG. 12B shows that the combined vias 145 are uniformly arranged or stacked within the stress buffer structure 133, such that the combined vias 145 have a uniform density (e.g., a uniform number of combined vias 145 per unit area) across the stress buffer structure 133, and over the semiconductor dies 150 and the encapsulant 132. For example, a spacing S1 defines a distance between adjacent combined vias 145 in a first direction (e.g., the x-direction), and a spacing S2 defines a distance between adjacent combined vias 145 in a second direction (e.g., the y-direction), wherein the first direction (e.g., the x-direction) is orthogonal to the second direction (e.g., the y-direction). The spacing S1 may be equal to the spacing S2. In addition, each combined via 145 has a middle via 140 with a diameter (e.g., diameter D2) that is equal to the diameters of the middle vias 140 of the other combined vias 145.

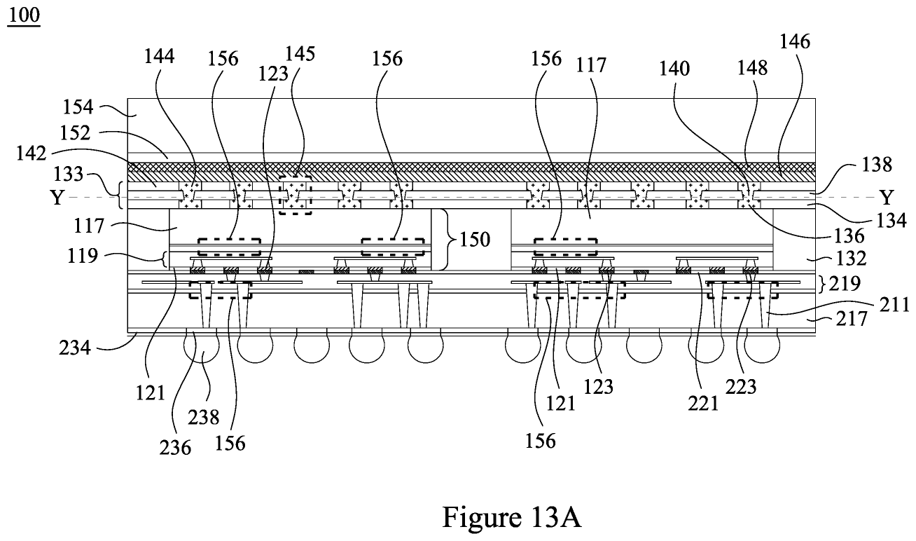

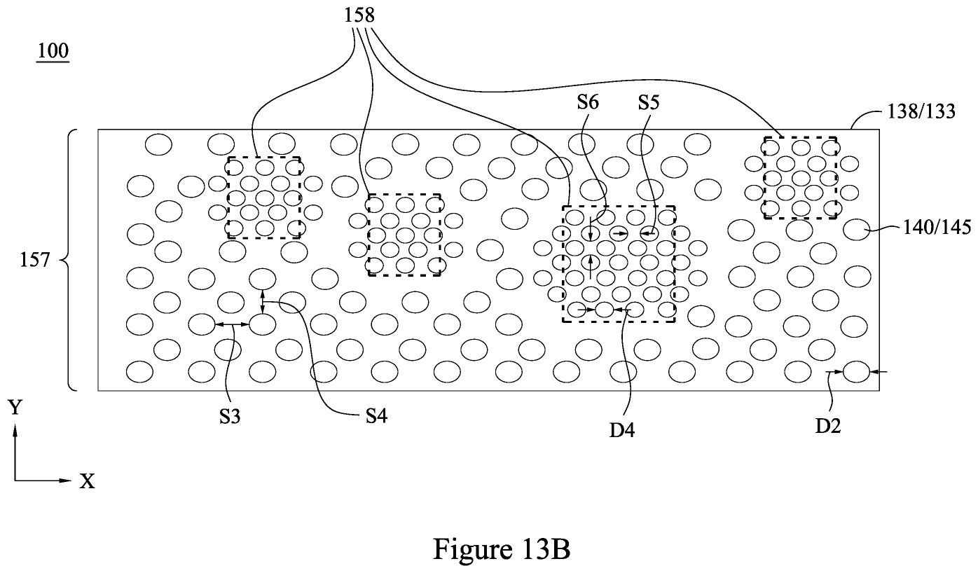

FIGS. 13A and 13B illustrate an alternative embodiment. Unless specified otherwise, like reference numerals in this embodiment (and subsequently discussed embodiments) represent like components in the embodiment shown in FIGS. 1 through 12B formed by like processes. Accordingly, the process steps and applicable materials may not be repeated herein.

FIG. 13A illustrates the formation of the conductive connectors 238 on the metallization patterns 236. FIG. 13B illustrates a top-down view of the integrated chip package 100 along a line Y-Y shown in FIG. 13A. In FIG. 13A, the conductive connectors 238 are formed using similar processes and similar materials as those that were described previously in FIG. 12A. FIG. 13A also shows hot spots 156, which are localized regions of the semiconductor dies 150 and the wafer 20 that experience significantly higher temperatures than the surrounding areas during operation of the integrated chip package 100.

In FIG. 13B, a top-down view is shown along a line Y-Y that is illustrated in FIG. 13A, wherein the line Y-Y passes through a center of the middle stress buffer layer 133b of the stress buffer structure 133. The FIG. 13B therefore shows the insulating layer 138 of the stress buffer structure 133, and the middle vias 140 of respective combined vias 145 that extend through the stress buffer structure 133. FIG. 13B further shows a first region 157, and second regions 158 within the first region 157, wherein each second region 158 is surrounded by the first region 157. Each second region 158 is a region of the stress buffer structure 133 that overlaps one or more hot spots 156 (shown previously in FIG. 13A) in the wafer 20 and/or the semiconductor dies 150. In the first region 157, the combined vias 145 are uniformly arranged or stacked within the stress buffer structure 133, such that the combined vias 145 have a uniform first density (e.g., a uniform number of combined vias 145 per unit area) across the first region 157. For example, in the first region 157, a spacing S3 defines a distance between adjacent combined vias 145 in a first direction (e.g., the x-direction), and a spacing S4 defines a distance between adjacent combined vias 145 in a second direction (e.g., the y-direction), wherein the first direction (e.g., the x-direction) is orthogonal to the second direction (e.g., the y-direction). The spacing S3 may be equal to the spacing S4. In addition, in the first region 157, each combined via 145 has a middle via 140 with a diameter (e.g., diameter D2) that is equal to the diameters of the middle vias 140 of the other combined vias 145 in the first region 157.

In the second regions 158, the combined vias 145 are uniformly arranged or stacked within the stress buffer structure 133, such that the combined vias 145 have a uniform second density (e.g., a uniform number of combined vias 145 per unit area) across the second regions 158. In an embodiment, the second density of the combined vias 145 in the second regions 158 is larger than the first density of the combined vias 145 in the first region 157. For example, in the second regions 158, a spacing S5 defines a distance between adjacent combined vias 145 in a first direction (e.g., the x-direction), and a spacing S6 defines a distance between adjacent combined vias 145 in a second direction (e.g., the y-direction), wherein the first direction (e.g., the x-direction) is orthogonal to the second direction (e.g., the y-direction). The spacing S5 may be equal to the spacing S6, and the spacing S5 and the spacing S6 may both be smaller than the spacing S3 and the spacing S4. In addition, in the second regions 158, each combined via 145 has a middle via 140 with a diameter (e.g., diameter D4) that is equal to the diameters of the middle vias 140 of the other combined vias 145 in the second regions 158. In an embodiment, the diameter D4 is smaller than the diameter D2.

In an embodiment, a density of the combined vias 145 in each second region 158 is different from densities of the combined vias 145 in each of the other second regions 158 and the first region 157.

Advantages can be achieved by forming the stress buffer structure 133 over and in physical contact with the semiconductor dies 150 and the encapsulant 132, wherein the stress buffer structure 133 comprises the first region 157 and the second regions 158, and wherein each second region 158 overlaps one or more hot spots 156 in the wafer 20 and/or the semiconductor dies 150. Each second region 158 is surrounded by the first region 157. In the first region 157, the combined vias 145 have a uniform first density (e.g., a uniform number of combined vias 145 per unit area) across the first region 157, and in the second regions 158, the combined vias 145 have a uniform second density (e.g., a uniform number of combined vias 145 per unit area) across the second regions 158, wherein the second density is larger than the first density. These advantages include the increased number of combined vias 145 per unit area in the second regions 158 resulting in an increased number of thermal conduction pathways for the extra heat generated in each hot spot 156 to be distributed through the stress buffer structure 133 and on to the metal heat spreader 154. This results in quicker and more efficient removal of heat from the hot spots 156 and the integrated chip package 100, resulting in an improvement in device reliability and device performance.

In FIG. 14, a package substrate 240 is coupled to the integrated chip package 100. The package substrate 240 may comprise an interposer, a package, a core substrate, a coreless substrate, a printed circuit board (PCB), or the like. In an embodiment, the package substrate 240 includes a substrate core 260 and bond pads 246 over the substrate core 260. The substrate core 260 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 260 may be an SOI substrate. Generally, an SOI substrate includes a layer of a semiconductor material such as epitaxial silicon, germanium, silicon germanium, SOI, SGOI, or combinations thereof. The substrate core 260 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for substrate core 260.

The substrate core 260 may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core 260 may also include metallization layers and vias (not shown), with the bond pads 246 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 260 is substantially free of active and passive devices.

In some embodiments, the conductive connectors 238 are reflowed to attach the integrated chip package 100 to the bond pads 246. The conductive connectors 238 electrically and/or physically couple the package substrate 240, including metallization layers in the substrate core 260, to the integrated chip package 100. In some embodiments, a solder resist 248 is formed on the substrate core 260. The conductive connectors 238 may be disposed in openings in the solder resist 248 to be electrically and mechanically coupled to the bond pads 246. The solder resist 248 may be used to protect areas of the substrate core 260 from external damage.

The conductive connectors 238 may have an epoxy flux (not shown) formed thereon before they are reflowed with at least some of the epoxy portion of the epoxy flux remaining after the integrated chip package 100 is attached to the package substrate 240. This remaining epoxy portion may act as an underfill to reduce stress and protect the joints resulting from reflowing the conductive connectors 238. In some embodiments, an underfill 250 may be formed between the integrated chip package 100 and the package substrate 240, and surrounding the conductive connectors 238. The underfill 250 may be formed by a capillary flow process after the coupling of the integrated chip package 100 to the package substrate 240 or may be formed by a suitable deposition method before the package substrate 240 is coupled to the integrated chip package 100.

In an embodiment, the package substrate 240 may comprise bond pads 252 over the substrate core 260. Conductive connectors 254 may be coupled to the bond pads 252 to allow for the electrical coupling of the package substrate 240 to external circuits or devices. The conductive connectors 254 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 254 may include a conductive material such as solder, copper, aluminum, gold, nickel, silver, palladium, tin, the like, or a combination thereof. In some embodiments, the solder resist 248 is formed on the substrate core 260 and the conductive connectors 254 may be disposed in openings in the solder resist 248 to be electrically and mechanically coupled to the bond pads 252. The solder resist 248 may be used to protect areas of the substrate core 260 from external damage.

In some embodiments, passive devices (e.g., surface mount devices (SMDs), not shown) may also be attached to the package substrate 240 (e.g., to the bond pads 246). For example, the passive devices may be bonded to a same surface of the package substrate 240 as the conductive connectors 238.

The embodiments of the present disclosure have some advantageous features. The embodiments include a method for the formation of an integrated chip package. Forming the integrated chip package comprises bonding two or more semiconductor dies (e.g., top dies) to a semiconductor wafer (e.g., a bottom die). A stress buffer structure is formed over and in physical contact with the two or more semiconductor dies (e.g., top dies). The stress buffer structure comprises one or more insulating layers with a plurality of copper vias that extend through the one or more insulating layers, wherein a percentage ratio of the total volume of the copper vias to the total volume of the stress buffer structure is in a range from 10 percent to 30 percent. A metal layer is formed over the stress buffer structure, and a thermal interface material (TIM) is applied to a top surface of the metal layer. A metal heat spreader (e.g., a copper lid) is subsequently placed on the integrated chip package, and the metal heat spreader makes contact with the metal layer by way of the TIM. As a result, mechanical stresses due to a mismatch in the co-efficient of thermal expansions of a first material (e.g., copper) of the metal heat spreader and a second material (e.g., silicon) of the two or more semiconductor dies (e.g. the top dies) are reduced. The stress buffer structure acts as an intermediate interface, absorbing or relaxing the mechanical stress caused by the mismatch in the co-efficient of thermal expansions between the first material and the second material. This reduces a risk of cracking at the interface between the two or more semiconductor dies (e.g. the top dies) and the metal heat spreader, and lowers the risk of delamination between the metal heat spreader and the two or more semiconductor dies (e.g. the top dies). In addition, the metal heat spreader and the stress buffer structure allow for improved and more effective heat dissipation from the integrated chip package, resulting in an improvement in device reliability and device performance.

In accordance with an embodiment, a method of manufacturing a semiconductor device includes bonding a first die and a second die to a first side of a substrate; forming a stress buffer structure over the first die and the second die, where the stress buffer structure includes a first portion of a first via extending through a first insulating layer; a second portion of the first via extending through a second insulating layer; and a third portion of the first via extending through a third insulating layer, where the second portion of the first via is disposed between the first portion of the first via and the third portion of the first via, and where a diameter of the second portion of the first via is smaller than diameters of the first portion of the first via and the third portion of the first via; and depositing a metal layer over the stress buffer structure. In an embodiment, the first insulating layer, the second insulating layer, and the third insulating layer include a low-temperature polyimide (LTPI) material. In an embodiment, the first via includes copper. In an embodiment, the diameter of the second portion of the first via decreases in a vertical direction from a top surface of the stress buffer structure towards a bottom surface of the stress buffer structure. In an embodiment, the method further includes before forming the stress buffer structure over the first die and the second die, forming a molding material over and around each of the first die and the second die; and performing a planarization process to expose top surfaces of the first die and the second die. In an embodiment, the method further includes coupling a heat spreader to a top surface of the metal layer, where the first die is thermally coupled to the heat spreader through the first via and the metal layer, and the first via is in physical contact with a top surface of the first die. In an embodiment, the stress buffer structure has a thickness that is up to 100 μm.

In accordance with an embodiment, a package includes a first die over and bonded to a first side of a second die; an encapsulant around the first die; and a stress buffer structure over the first die and the encapsulant, where the stress buffer structure includes a plurality of insulating layers; and a plurality of first vias, where each first via of the plurality of first vias extends through the plurality of insulating layers, where the plurality of first vias include copper, and a percentage ratio of a total volume of copper of the plurality of first vias to a total volume of the stress buffer structure is in a range from 10 to 30 percent. In an embodiment, each insulating layer of the plurality of insulating layers includes a low-temperature polyimide (LTPI) material. In an embodiment, the plurality of first vias have a uniform density within the stress buffer structure. In an embodiment, first ones of the plurality of first vias in a first region of the stress buffer structure have a first density, and second ones of the plurality of first vias in a second region of the stress buffer structure have a second density, where the first density and the second density are different. In an embodiment, the package further includes a metal layer over the stress buffer structure; and a heat dissipation structure over and coupled to the metal layer. In an embodiment, each first via of the plurality of first vias includes a top portion with a first diameter; a middle portion with a second diameter; and a bottom portion with a third diameter, where the second diameter is smaller than the first diameter and the third diameter. In an embodiment, the package further includes a package substrate coupled to a second side of the second die using conductive connectors.

In accordance with an embodiment, a package includes a top die bonded to a bottom die; a molding compound surrounding the top die; a first stress buffer layer over the top die, the first stress buffer layer including a plurality of first vias extending through a first dielectric material, where a first one of the plurality of first vias is in physical contact with a substrate of the top die, and where the substrate includes silicon; a second stress buffer layer over the first stress buffer layer, the second stress buffer layer including a plurality of second vias extending through a second dielectric material, where each of the plurality of second vias overlaps and is in physical contact with a respective one of the plurality of first vias; and a heat spreader over and thermally coupled to the plurality of first vias and the plurality of second vias. In an embodiment, the package further includes a third stress buffer layer over the second stress buffer layer, the third stress buffer layer including a plurality of third vias extending through a third dielectric material, where a portion of each of the plurality of third vias overlaps and is in physical contact with a respective one of the plurality of second vias. In an embodiment, the package further includes a metal layer disposed between the third stress buffer layer and the heat spreader, where the metal layer is in physical contact with top surfaces of the plurality of third vias. In an embodiment, the plurality of first vias, the plurality of second vias, and the plurality of third vias include copper, and a percentage ratio of a total volume of copper of the plurality of first vias, the plurality of second vias, and the plurality of third vias to a total volume of the first stress buffer layer, the second stress buffer layer, and the third stress buffer layer is in a range from 10 to 30 percent. In an embodiment, the first dielectric material, the second dielectric material, and the third dielectric material include a low-temperature polyimide (LTPI) material. In an embodiment, a diameter of each of the plurality of second vias decreases in a vertical direction from a top surface of the second stress buffer layer towards a bottom surface of the second stress buffer layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
bonding a first die and a second die to a first side of a substrate;
forming a stress buffer structure over the first die and the second die, wherein the stress buffer structure comprises:
a first portion of a first via extending through a first insulating layer;
a second portion of the first via extending through a second insulating layer; and
a third portion of the first via extending through a third insulating layer, wherein the second portion of the first via is disposed between the first portion of the first via and the third portion of the first via, and wherein a diameter of the second portion of the first via is smaller than diameters of the first portion of the first via and the third portion of the first via; and
depositing a metal layer over the stress buffer structure.

2. The method of claim 1, wherein the first insulating layer, the second insulating layer, and the third insulating layer comprise a low-temperature polyimide (LTPI) material.

3. The method of claim 2, wherein the first via comprises copper.

4. The method of claim 2, wherein the diameter of the second portion of the first via decreases in a vertical direction from a top surface of the stress buffer structure towards a bottom surface of the stress buffer structure.

5. The method of claim 1, further comprising:
before forming the stress buffer structure over the first die and the second die, forming a molding material over and around each of the first die and the second die; and
performing a planarization process to expose top surfaces of the first die and the second die.

6. The method of claim 1, further comprising coupling a heat spreader to a top surface of the metal layer, wherein the first die is thermally coupled to the heat spreader through the first via and the metal layer, and the first via is in physical contact with a top surface of the first die.

7. The method of claim 1, wherein the stress buffer structure has a thickness that is up to 100 μm.

8. A package comprising:
a first die over and bonded to a first side of a second die;
an encapsulant around the first die; and
a stress buffer structure over the first die and the encapsulant, wherein the stress buffer structure comprises:
a plurality of insulating layers; and
a plurality of first vias, wherein each first via of the plurality of first vias extends through the plurality of insulating layers, wherein the plurality of first vias comprise copper, and a percentage ratio of a total volume of copper of the plurality of first vias to a total volume of the stress buffer structure is in a range from 10 to 30 percent.

9. The package of claim 8, wherein each insulating layer of the plurality of insulating layers comprises a low-temperature polyimide (LTPI) material.

10. The package of claim 8, wherein the plurality of first vias have a uniform density within the stress buffer structure.

11. The package of claim 8, wherein first ones of the plurality of first vias in a first region of the stress buffer structure have a first density, and second ones of the plurality of first vias in a second region of the stress buffer structure have a second density, wherein the first density and the second density are different.

12. The package of claim 8 further comprising:
a metal layer over the stress buffer structure; and
a heat dissipation structure over and coupled to the metal layer.

13. The package of claim 8, wherein each first via of the plurality of first vias comprises:
a top portion with a first diameter;
a middle portion with a second diameter; and
a bottom portion with a third diameter, wherein the second diameter is smaller than the first diameter and the third diameter.

14. The package of claim 8 further comprising:
a package substrate coupled to a second side of the second die using conductive connectors.

15. A package comprising:
a top die bonded to a bottom die;
a molding compound surrounding the top die;
a first stress buffer layer over the top die, the first stress buffer layer comprising a plurality of first vias extending through a first dielectric material, wherein a first one of the plurality of first vias is in physical contact with a substrate of the top die, and wherein the substrate comprises silicon;
a second stress buffer layer over the first stress buffer layer, the second stress buffer layer comprising a plurality of second vias extending through a second dielectric material, wherein each of the plurality of second vias overlaps and is in physical contact with a respective one of the plurality of first vias; and
a heat spreader over and thermally coupled to the plurality of first vias and the plurality of second vias.

16. The package of claim 15, further comprising:
a third stress buffer layer over the second stress buffer layer, the third stress buffer layer comprising a plurality of third vias extending through a third dielectric material, wherein a portion of each of the plurality of third vias overlaps and is in physical contact with a respective one of the plurality of second vias.

17. The package of claim 16, further comprising:
a metal layer disposed between the third stress buffer layer and the heat spreader, wherein the metal layer is in physical contact with top surfaces of the plurality of third vias.

18. The package of claim 16, wherein the plurality of first vias, the plurality of second vias, and the plurality of third vias comprise copper, and a percentage ratio of a total volume of copper of the plurality of first vias, the plurality of second vias, and the plurality of third vias to a total volume of the first stress buffer layer, the second stress buffer layer, and the third stress buffer layer is in a range from 10 to 30 percent.

19. The package of claim 16, wherein the first dielectric material, the second dielectric material, and the third dielectric material comprise a low-temperature polyimide (LTPI) material.

20. The package of claim 15, wherein a diameter of each of the plurality of second vias decreases in a vertical direction from a top surface of the second stress buffer layer towards a bottom surface of the second stress buffer layer.
